(19) United States
(12) Patent Application Publication
(10) Pub. No.: US 2013/0107902 A1
(43) Pub. Date: May 2, 2013

(54) CONTINUOUS WAVE ORGANIC SEMICONDUCTOR LASERS BY TRIPLET MANAGERS

(71) Applicants: Stephen R. Forrest, Ann Arbor, MI (US); Yifan Zhang, Ann Arbor, MI (US)

(72) Inventors: Stephen R. Forrest, Ann Arbor, MI (US); Yifan Zhang, Ann Arbor, MI (US)

(73) Assignee: The Regents of the University of Michigan, Ann Arbor, MI (US)

(21) Appl. No.: 13/283,284

(22) Filed: Oct. 27, 2011

(51) Int. Cl. H01S 5/36

(52) U.S. Cl. 372/45.01

(57) ABSTRACT

A first device is provided. The device includes an organic semiconductor laser. The organic semiconductor laser further includes an optical cavity and an organic layer disposed within the optical cavity. The organic layer includes: an organic host compound; an organic emitting compound capable of fluorescent emission; and an organic dopant compound. The organic dopant compound may also be referred to herein as a “triplet manager.” The triplet energy of the organic dopant compound is lower than or equal to the triplet energy of the organic host compound. The triplet energy of the organic dopant compound is lower or equal to than the triplet energy of the organic emitting compound. The singlet energy of the organic emitting compound is lower than the singlet energy of the organic host compound.

This application is related to U.S. application Ser. No. 12/117,926, filed May 27, 2011, which claims priority to U.S. 61/396,862, filed Jun. 3, 2010, and U.S. 61/398,627, filed Jun. 29, 2010. These related applications are incorporated by reference in their entireties.

This invention was made with government support under FA9550-10-1-0339 awarded by the AFOSR (AirForce Office of Scientific Research). The government has certain rights in the invention.

The claimed invention was made by, on behalf of, and/or in connection with one or more of the following parties to a joint university corporation research agreement: Regents of the University of Michigan, Princeton University, The University of Southern California, and the Universal Display Corporation. The agreement was in effect on and before the date the claimed invention was made, and the claimed invention was made as a result of activities undertaken within the scope of the agreement.

### FIELD OF THE INVENTION

The present invention relates to lasers using organic materials.

### BACKGROUND

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting devices (OLEDs), organic phototransistors, organic photovoltaic cells, and organic photo detectors.

Various ways to deposit the organic materials used to fabricate organic devices are known, such as vacuum thermal evaporation, solution processing, organic vapor phase deposition, and organic vapor jet printing.

### SUMMARY OF THE INVENTION

A first device is provided. The device includes an organic semiconductor laser. The organic semiconductor laser further includes an optical cavity and an organic layer disposed within the optical cavity. The organic layer includes: an organic host compound; an organic emitting compound capable of fluorescent emission; and an organic dopant compound. The organic dopant compound may also be referred to herein as a “triplet manager.” The triplet energy of the organic dopant compound is lower than or equal to the triplet energy of the organic host compound. The triplet energy of the organic dopant compound is lower or equal to than the triplet energy of the organic emitting compound. The singlet energy of the organic emitting compound is lower than the singlet energy of the organic host compound.

Preferably, the singlet energy of the organic emitting compound is lower than the singlet energy of the organic dopant compound.

Preferably, the organic dopant compound does not strongly absorb the fluorescent emission of the organic emitting compound.

In one embodiment, the first device further includes an optical pump optically coupled to the organic layer.

In one embodiment, the organic semiconductor laser further includes an anode and a cathode. The organic layer is disposed between the anode and the cathode. A hole transport layer is disposed between the organic layer and the anode. An electron transport layer is disposed between the organic layer and the cathode. The organic dopant compound is present only in the emissive layer.

Preferably, the triplet decay time of the dopant compound is shorter than the triplet decay time of the emitting compound.

Preferably, the concentration of the dopant compound is 10 wt %-90 wt %, and the concentration of the emitting compound is 0.5 wt %-5 wt %.

Preferably, the organic emitting compound is capable of fluorescent emission at room temperature.

Preferably, the dopant compound is selected from the group consisting of: anthracene, tetracene, rubrene, and perylene and their derivatives. More preferably, the dopant compound is selected from anthracene and its derivatives are particularly preferred. More preferably, the dopant compound is ADN.

In some embodiments, the dopant compound is a phosphor. In some embodiments, the dopant compound is a fluorophore.

The first device may be a consumer product.

A method is provided. An organic semiconductor laser is provided. The organic semiconductor laser further includes an optical cavity and an organic layer disposed within the optical cavity. The organic layer includes: an organic host compound; an organic emitting compound capable of fluorescent emission; and an organic dopant compound. The organic dopant compound may also be referred to herein as a “triplet manager.” The triplet energy of the organic dopant compound is lower than or equal to the triplet energy of the organic host compound. The triplet energy of the organic dopant compound is lower or equal to than the triplet energy of the organic emitting compound. The singlet energy of the organic emitting compound is lower than the singlet energy of the organic host compound. The organic semiconductor laser is pumped to achieve lasing.

In one embodiment, the pumping is optical pumping.

In one embodiment, the pumping is electrical pumping.

When the organic semiconductor laser is pumped, lasing is achieved for at least 1 microsecond.

In some embodiments, the organic semiconductor laser is pumped at a power that exceeds the pulse threshold.

In some embodiments, the organic semiconductor laser is pumped at a power that exceeds the continuous wave threshold.

In some embodiment, the organic semiconductor laser is pumped at a power that exceeds the continuous wave threshold for at least 1 microsecond, and more preferably for at least 100 microseconds.

### BRIEF DESCRIPTION OF THE DRAWINGS

FIG. 1 shows separate channels for singlet (S) and triplet (T) formation and transfer in triplet managed lasers. Singlets are generated (circles) on both Alq₃ and ADN, and Förster transferred (solid arrows) to DCM2. Triplets are generated by intersystem crossing (ISC) and collected by ADN through Dexter transfer (dashed arrows).

FIG. 2 shows (a) Photoluminescence (PL), and (b) lasing transients measured at 1.6 kW/cm² pump intensity for different host blends. The PL transients are normalized by the peak intensities, and lasing transients are normalized to 1 for x=0, 10, and 30 ADN blends, and to 5 for x=50 and 70. The fits are obtained by the model described in text with parameters summarized in Table 1. Inset: Lasing spectrum of an x=70 OSL.

FIG. 3 shows simulated threshold singlet population, S_{TH}(t) with (x=70, stars) and without (squares) a triplet manager, and S(t) (lines) for the x=70 OSL. Lasing occurs when S≧S_{TH}. The dashed lines correspond to lasers that have exceeded their pulsed threshold singlet population (Sps), but not their CW threshold (S_{CW}). Left Inset: Streak camera image of laser emission for a triplet-managed OSL (x=70) measured at 2.4 kW/cm² pump intensity, 18 μs pulse width. Right Inset: Simulated lasing duration evolution with increasing pump power for x=70 triplet managed OSL.

FIG. 4 shows: 4(a) Photoluminescence (PL) spectra of thin film ADN (squares), Alq₃ (circles), and DCM2 doped in an x % ADN/(100−x)% Alq₃ blend with x=0 (stars) and 70 (triangles). The shaded region corresponds to where the DCM2 absorption coefficient is >4×10⁴ cm⁻¹, implying efficient energy transfer from both ADN and Alq₃. 4(b) phosphorescence of Alq₃, DCM2, and ADN measured at 14 K, the fits are to double-peak Gaussian for Alq3 and single-peak Gaussians for the rest.

FIG. 5 shows a probe pulse PL spectrum with and without the pump pulse for x=0 (a) and x=70 (b) films. The 200 nm film was grown on SiO₂ (2 μm)/Si substrate.

FIG. 6 illustrates the calculation of an absorption coefficient for x=0 and 70 from the data in FIG. 5.

FIG. 7 shows a streak camera image of laser emission for x=70 triplet managed OSL measured at 2.4 kW/cm² pump intensity and 100 μs pulse width integrated over 10 pulses. Note that the color map uses logarithm scale. Lasing duration (characterized by narrow spectrum) is approximately 55 μs. The lasing wavelength is slightly different from the inset of FIG. 3 because these two lasers are not fabricated at the same time and their gain medium thicknesses or grating periods can be slightly different.

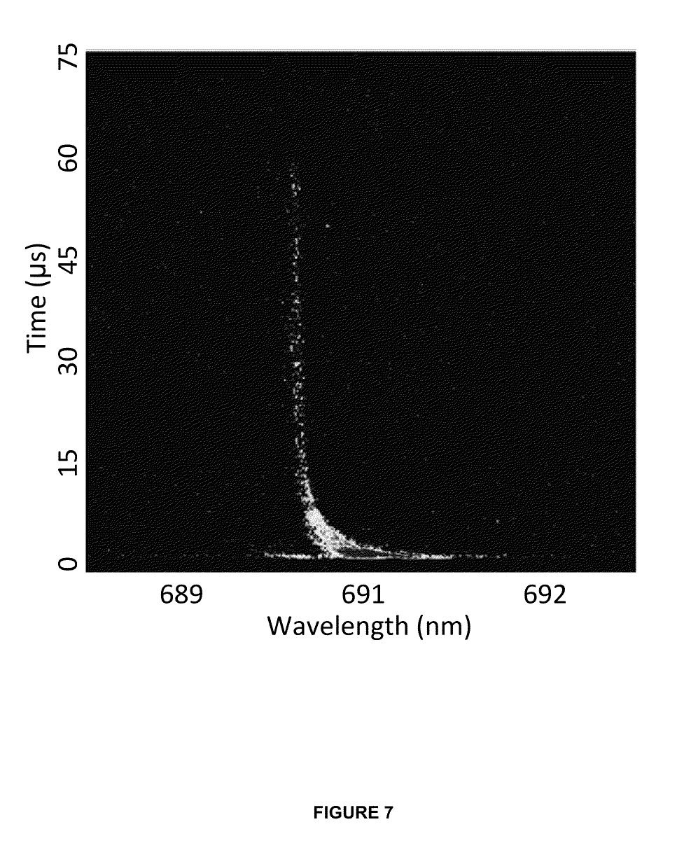

### DETAILED DESCRIPTION

A model has been developed for organic lasers that predicts two threshold pump intensities in optically pumped organic semiconductor lasers (OSLs); one for pulsed lasing, I_{PS}, and another for continuous-wave (CW) lasing, I_{CW}. The theory predicts a decrease in I_{CW} from 32 kW/cm², or well above the damage threshold, to 2.2 kW/cm², for a laser employing 4-(dicyanomethylene)-2-methyl-6-julolidyl-9-enyl-4H-pyran (DCM2) doped tris(8-hydroxyquinoline)aluminum (Alq₃) if the triplets can be effectively removed from the emissive guest. Based on this analysis, it has been demonstrated that the lasing duration can be extended to nearly 100 μs, ultimately limited by degradation of the lasing medium when a “triplet manager” molecule, 9,10-di(naphtha-2-yl)anthracene (ADN), is blended into the gain region of a distributed feedback OSL. The triplet manager facilitates radiative singlet transfer while suppressing non-radiative triplet transfer to the emitter molecule, thus reducing the triplet-induced losses. Our theory conclusively shows that these lasers have entered the CW lasing regime.

Optically pumped organic semiconductor lasers (OSLs) with low thresholds and wide spectral tuning ranges have attracted interest since their demonstration 15 years ago. However, a significant obstacle to the application of OSLs has been their limitation to only pulsed operation with a maximum duration of several tens of nanoseconds. This limitation is imposed by the build-up of triplet (T) excitons in the gain region that are generated from intersystem crossing (ISC) of radiative singlets (S). Since the relaxation from T to the ground state is quantum mechanically forbidden, the lifetime of T exciton is large (˜ms) compared to S (˜ns), allowing the T population can accumulate over time. The high T population, together with overlapping S emission and T absorption, results in singlet and photon losses that ultimately shut down lasing, thereby preventing continuous-wave (CW) operation.

While triplet losses in liquid dye lasers can be mitigated by using quencher molecules with triplet energies lower than that of the dye, no CW operation has been realized without dye circulation. For OSLs, gain medium circulation is not possible; however, several efforts have been made to mitigate, although not eliminate triplet losses to the extent that CW operation can be achieved. Bornemann, et al., Opt. Lett. 31 (11), 1669-1671 (2006), have used a rapidly rotating substrate to demonstrate a CW solid state dye laser, but the output was unstable. Schols, et al., ChemPhysChem 10 (7), 1071-1076 (2009), have shown that “scavengers” can be used to de-excite triplets, but no lasing improvement was demonstrated. Rabe, et al., Appl. Phys. Lett. 89 (8), 081115 (2006), and Leahnhardt, et al. Org. Electron. 12 (8), 1346-1351 (2011), demonstrated a polymer OSL pumped by very low duty cycle (<0.1%) pulses to extend the total duration to 400 μs, although this is not true CW operation.

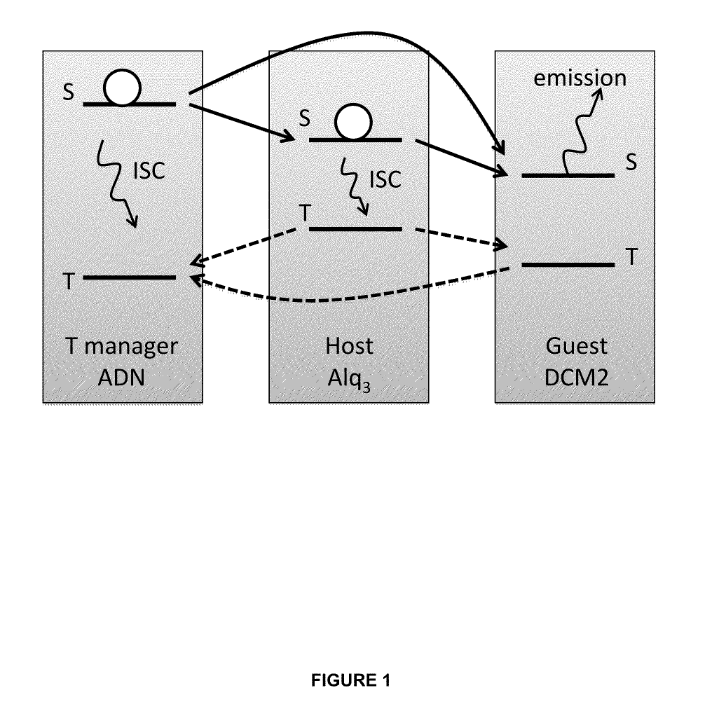

Here, we introduce a “triplet manager” into the gain region along with the guest emitter and host molecules. The manager reduces the emitter triplet population, thus extending the lasing duration. The inset of FIG. 1 shows the triplet management concept. The manager has lower triplet energy and higher singlet energy than the emitter. When either the host or manager molecules are excited, Förster transfer of S-states to the emitter is highly efficient. Furthermore, Dexter transfer of triplets lead to their trapping on the manager since it has lower triplet energy than both the guest and the host. The manager triplet absorption is shifted from the guest emission and thus the trapped triplets do not contribute to optical losses or singlet quenching.

The 200 nm thick OSL active region consists of the manager, 9,10-di(naphtha-2-yl)anthracene (ADN), co-deposited into the conventional guest-host gain medium consisting of 2 vol % of the red emitting 4-(dicyanomethylene)-2-methyl-6-julolidyl-9-enyl-4H-pyran (DCM2) in tris(8-hydroxyquinoline) Al (Alq₃). The S and T energies are determined from fluorescence at room temperature, and phosphorescence at 14K respectively, see EPAPS. Here, ADN has lower T (1.69 eV) and higher S energy (2.83 eV) than Alq₃ (T=1.99 eV and S=2.38 eV). Furthermore, S=2.03 eV and T=1.74 eV for DCM2. This system, therefore, is energetically consistent with FIG. 1.

The manager concentration in (100−x) vol % Alq₃ is x vol % ADN (x=0, 10, 30, 50, 70, 100). Blended films were deposited by thermal evaporation in high vacuum (10⁻⁷ Ton) on quartz, Si, and 2 μm thick SiO₂-on-Si substrates for characterizing absorption, photoluminescence (PL), and triplet absorption, respectively. The same films were deposited on gratings with a period of 430 nm±5 nm and a 50 nm depth on the SiO₂-on-Si to form distributed feedback (DFB) OSLs. Output from a 0.6 W laser diode at wavelength 2=405 nm was focused to a 150 μm×250 μm spot to optically pump the thin film. Alq₃ and ADN pure film absorption coefficients were measured to be 4.8×10⁴ cm⁻¹ and 9.1×10⁻⁴ cm⁻¹ at λ=405 nm, and are assumed to contribute to the total blend film absorption proportionate to their volume. All measurements were performed in N₂ ambient to minimize film degradation.

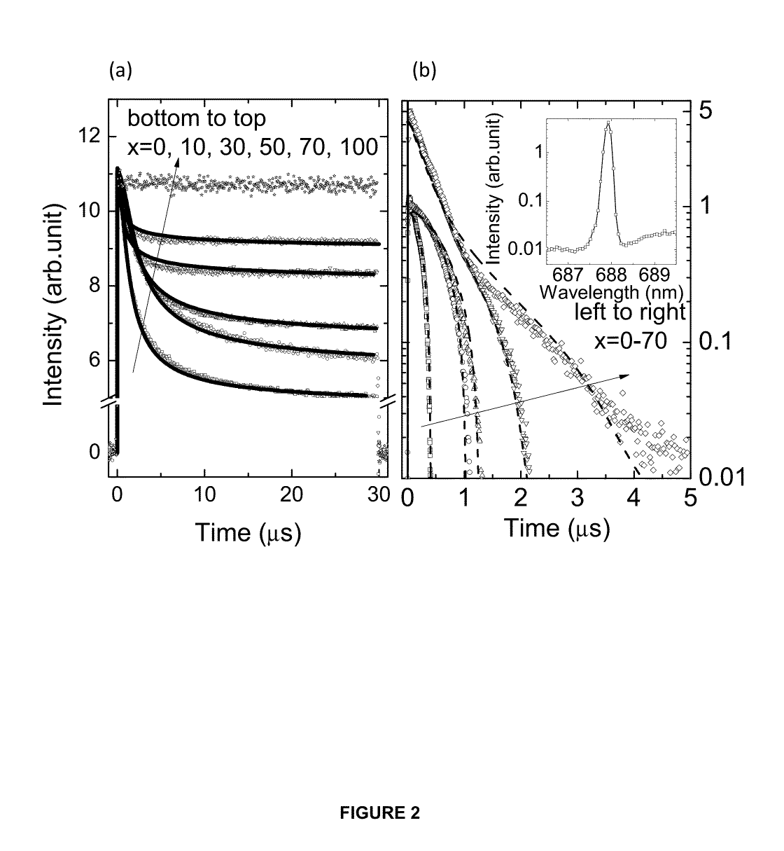

FIGS. 2(a) and (b) shows the PL and lasing transients pumped at 1.6 kW/cm². From FIG. 2(a), the Alq₃ host undergoes a 55% reduction in PL to its steady state value within 30 μs of the onset of the pump. Previous studies have shown that this intensity roll-off is due to singlet quenching from S-T annihilation. That is, following the onset, the S density rapidly reaches a peak and subsequently decays due to annihilation by the slowly increasing T population. The existence of the long-term steady state PL intensity below its peak suggests saturation of the guest triplet population. By including the ADN manger into the host blend with x=10 to 70, the PL transient quenching is reduced to 17%. Further increasing to x>70 can eliminate quenching entirely. We infer, therefore, that triplets are transferred from Alq₃ to DCM2, while the transfer from ADN to DCM2 is forbidden, consistent with the triplet energy relation T(Alq₃)>T(DCM2)>T(ADN). Note, however, that morphology degradation under high pump intensity occurs for x>50, consistent with the previous observation of morphological instability of ADN.

In FIG. 2(b), more than a ten-fold increase in lasing time (from approximately 400 ns to 4.5 μs) is observed when x increases from 0 to 70. Lasing is not observed for x=100 due to degradation. The inset shows a typical lasing spectrum of a 70% ADN OSL centered at 2=687.9 nm, with a full width half maximum of 0.15 nm limited by the spectrometer resolution. The threshold pulsed pump intensity, I_{PS} (characterized by an abrupt spectral narrowing from >30 nm to <0.5 nm, and a significant increase in the slope efficiency) was obtained using a 30 ns pump pulse (Table 1).

TABLE 1
Parameters for PL and lasing transients fits, and the corresponding, measured pulsed
(I_{PS}) and calculated CW (I_{CW}) lasing threshold intensities

| Device | I_{TH}† | k_{HG}* | k_{ISC}* | N₀* | σ_{TT}† | σₛₜᵢₘ* | I_{CW} |
|---|---|---|---|---|---|---|---|
| (% ADN) | (kW/cm²) | (10¹⁰/s) | (10⁷/s) | (10¹⁸/cm³) | (10⁻¹⁷ cm²) | (10⁻¹⁶ cm²) | (kW/cm²) |
| 0 | 0.93 | 4.0 | 3.3 | 5.0 ± 0.4 | 4.0 ± 0.3 | 1.9 | 32 |
| 10 | 0.75 | 3.5 | 2.6 | 3.9 ± 0.3 | 3.8 ± 0.3 | 2.0 | 19 |
| 30 | 0.72 | 13 | 2.3 | 2.8 ± 0.3 | 3.6 ± 0.4 | 2.4 | 8.8 |
| 50 | 0.45 | 3.0 × 10³ | 1.7 | 1.5 ± 0.2 | 4.3 ± 0.6 | 2.1 | 3.7 |
| 70 | 0.43 | 5.0 × 10⁵ | 1.3 | 0.92 ± 0.08 | 4.1 ± 0.4 | 2.3 | 2.2 |

†Parameters from measurement
*Parameters from fits to data

To understand the transient PL and lasing dynamics, we extend previous work ENREF 8 to include triplet Dexter transfer from host blend to guest, and guest triplet saturation. Hence, the coupled laser rate equations are:

$$\begin{matrix}\frac{d S}{d t} = \frac{η I}{{e}_{p} d} - {k}_{S} S - {k}_{ISC} S - {k}_{ST} {ST}_{G} - γ \frac{c}{{n}_{eff}} P , & ( 1 ) \\ \frac{d {T}_{H}}{d t} = {k}_{ISC} S - {k}_{HG} exp ( - \frac{2}{L} \sqrt[3]{\frac{1}{{N}_{0} - {T}_{G}}} ) {T}_{H} , & ( 2 ) \\ \frac{d {T}_{G}}{d t} = {k}_{HG} exp ( - \frac{2}{L} \sqrt[3]{\frac{1}{{N}_{0} - {T}_{G}}} ) {T}_{H} , & ( 3 ) \\ \frac{d P}{d t} = ( Γ γ - {α}_{CAV} - Γ {σ}_{TT} {T}_{G} ) \frac{c}{{n}_{eff}} P + Γ β {k}_{S} S , & ( 4 )\end{matrix}$$

where S, T_{H}, T_{G}, P are guest singlet, host blend triplet (including both ADN and Alq₃), guest triplet, and lasing mode photon densities, respectively, t is time, η is the fraction of the pump emission absorbed by the organic film, I is the pump intensity, eₚ=3.06 eV is the pump photon energy, d=200 nm is the OSL gain medium thickness, kₛ=(6.7±0.5)×10⁸ s⁻¹ is the guest S natural decay rate (measured from a 2% DCM2:Alq₃ film excited by 1.5 ns width N₂ laser pulses), k_{ISC} is the host ISC rate, k_{ST} is the guest S-T annihilation rate, γ=σₛₜᵢₘS is the gain, σₛₜᵢₘ is the stimulated emission cross-section, c is the speed of light, and n_{eff}=1.6 and Γ=0.69 are the effective refractive index and optical confinement factor for the SiO₂ (n=1.48)/organic (n=1.82)/air (n=1) waveguide.²⁴ Also, k_{HG} is the host-guest Dexter transfer coefficient, L is the guest-host van der Waals radius (˜1 nm), N₀ is the guest triplet saturation population, α_{CAV} is the cavity loss without contributions from triplet absorption, α_{TT}, and σ_{TT} is the guest triplet absorption cross-section, and β≈10⁻⁴ is the spontaneous emission factor²⁵. For PL, we have P=0, and the intensity is proportional to S. We assume that the host triplet population does not interact with S or P; this is tested by fits to the data as well as via direct triplet absorption measurements. Now, N₀ is determined from the saturation of PL quenching, and due to the balance of triplet transfer from Alq₃ to DCM2, and triplet trapping on ADN. Introducing N₀ avoids the complication of treating individual triplet transfer in the ternary blend.

Free parameters k_{ST}, k_{ISC}, k_{HG}, and N₀ are used in fitting the PL transients. To test for model consistency, transients at four different pump intensities (1.6, 1.3, 0.93, and 0.56 kW/cm²) yield a single set of parameter values summarized in Table 1. For all films, k_{ST}=2.0×10¹⁰ cm³/s, as expected for guest S-T annihilation due to resonant energy transfer that is only dependent on DCM2 S emission and T absorption. As x increases, fewer triplets are transferred from Alq₃ to DCM2 and more are trapped on ADN; thus Nₒ decreases from 5.0×10¹⁸ cm⁻³ to 9.2×10¹⁷ cm⁻³ when x=70, leading to decreased PL transient roll-off. The ˜10⁵ increase in k_{HG} seems surprising, however, the Dexter transfer rate is determined by

$${k}_{Dex} = {k}_{HG} exp [ - \frac{2}{L} \sqrt[3]{\frac{1}{{N}_{0} - {T}_{G}}} ] .$$

Thus, for T_{G}=0.7Nₒ, k_{Dex} only increases from 7.6×10⁴/s (x=0) to 4.4×10⁵/s (x=70), consistent with the shorter PL quenching time for higher x.

To model the lasing transients in FIG. 2(b), three additional parameters, σ_{TT}, σₛₜᵢₘ, and α_{CAV} are required. Here, α_{TT}(λ) was measured following Lehnhardt, et al., Phys. Rev. B 81 (16), 165206 (2010). (see EPAPS), and σ_{TT}=α_{TT}/N₀ is shown in Table 1 at λ=680 nm. The nearly constant α_{TT}(λ) spectra and σ_{TT} for all x are consistent with the assumption that only guest triplet absorbs the lasing emission (i.e. host and manager absorptions are negligible). Furthermore, α_{CAV}=ΓσₛₜᵢₘS_{PS}, where S_{PS}=ηI_{PS}/(eₚdk_{S}) is the pulse threshold S population, where T build-up under short excitation pulses is negligible. With these measurements and assumptions, the lasing transients are fit using only a single free parameter, σₛₜᵢₘ (Table 1). We note that the effect of ADN as a triplet manager lies in its ability to decrease Nₒ, while k_{ST} and σ_{TT} remain unchanged since they are intrinsic to DCM2.

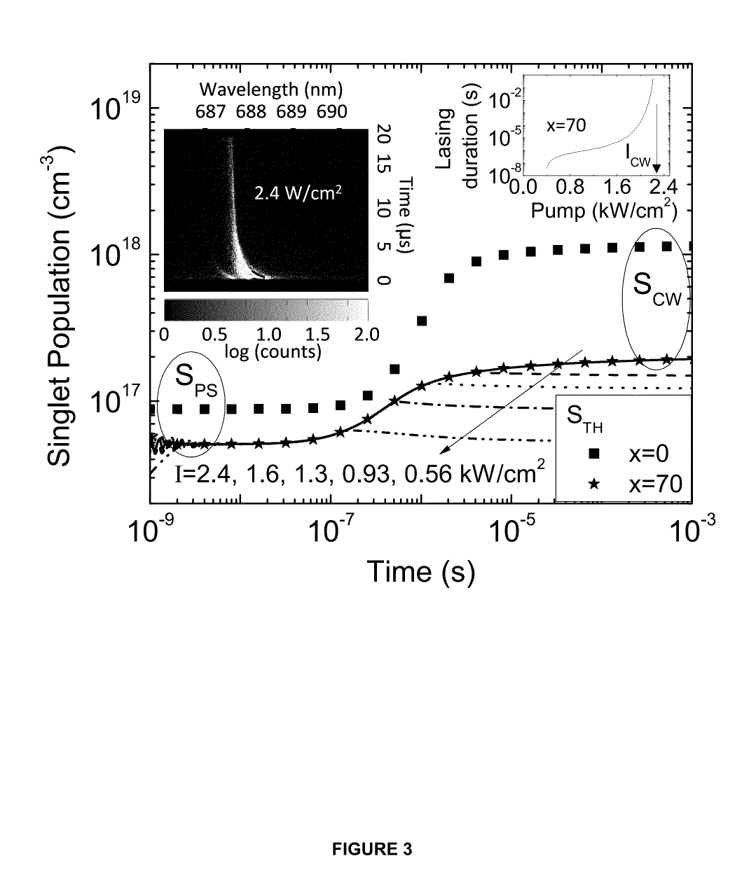

The net gain g(t)=ΓσₛₜᵢₘS(t)−α_{CAV}−Γσ_{TT}T_{G}(t)=0 determines the threshold S population dynamics, S_{TH}(t), which are plotted in FIG. 3 for the Alq₃ host (squares) and the optimized (x=70) blend host (stars), using parameters in Table 1. Surprisingly, two distinct threshold S populations emerge from the fits, with a CW threshold population (S_{CW}) occurring at a density larger than that needed for pulsed lasing (S_{PS}). As t→0, triplet loss Γσ_{TT}T_{G}<<α_{CAV}, giving S_{PS}=α_{CAV}/(Γσₛₜᵢₘ). With time, T_{G} increases, concomitantly increasing the associated loss until Γσ_{TT}T_{G}>α_{CAV}. Finally, T_{G} reaches its saturation density, N₀, at which point the triplet loss can no longer increase, giving S_{CW}(=(α_{CAV}+Γσ_{TT}N₀)/(Γσₛₜᵢₘ). FIG. 3 also shows S(t) for several pump intensities, I, for the host-manager blend, with the lasing duration vs. I plotted in the inset. Due to the saturation of T_{G} and thus S_{TH}, at I greater than the CW pump intensity threshold, I_{CW}=2.2 kW/cm², the lasing duration is no longer affected by triplet loss, and approaches infinity. Table I also gives I_{CW} for all x in blended hosts. With larger N₀ and thus increased triplet loss, the Alq₃-host OSL has I_{CW}=32 kW/cm². Due to organic film damage at such high intensities, the CW lasing threshold in the absence of a manager has not been previously reported.

Neglecting the change in singlet population due to stimulated emission (c.f. Eq. (1)), the CW threshold is approximately:

$${I}_{CW} ( {N}_{0} ) = {e}_{p} d ( {k}_{S} + {k}_{ISC} + {k}_{ST} {N}_{0} ) \frac{{α}_{CAV} + Γ {σ}_{TT} {N}_{0}}{η {Γσ}_{stim}} , \qquad ( 5 )$$

compared to the pulse threshold I_{PS}=I_{CW}=(N₀≈0). From Eq. (5), I_{CW} is a quadratic function of guest triplet saturation population: k_{ST}N₀ is from S-T quenching that reduces the gain; and Γσ_{TT}N₀ is due to triplet absorption, increasing loss.

To test the existence of this CW regime, we excited an Alq₃/ADN (x=70)/DCM2 laser at 2.4 kW/cm², or just above the calculated value of I_{CW} using the parameters in Table I. FIG. 3, left inset, shows a streak camera image of this emission over 20 μs duration. Lasing becomes weaker (leading to the apparent spectral narrowing) but does not turn off at the end of the long pulse, consistent with theory. Indeed, we observed nearly 100 μs lasing duration (see EPAPS) when pumped by a single pulse, although film degradation due to high optical pump intensities ultimately limits the lasing duration. Hence, while this OSL has clearly exceeded its CW threshold, the laser operates quasi-CW due to material degradation.

Interestingly, the lasing wavelength blue shifts from λ=288.1 nm to 687.7 nm during the lasing period, shown in FIG. 3, left inset. Wavelength shifts have been observed in liquid dye lasers where they have been attributed to the competition of triplet absorption with the gain spectrum. In thin film single mode DFB OSLs where the triplet absorption is largely constant (see EPAPS), the shift is more likely due to changes in the effective refractive index with increasing T density.

We note that I_{CW} can be further reduced and the lasing time extended by using a more stable, lower triplet energy manager, and with a better match between the manager emission and the guest absorption than is achieved with ADN. Then, the smaller saturation guest triplet population contributes negligible loss, in which case I_{CW}→I_{PS}. The design concept can be applied to the eventual development of electrically pumped organic semiconductor lasers, where 75% of the injected electrons result in triplets compared to only a few percent in optical pumping.

In conclusion, we show the existence of a CW threshold at a higher pump intensity than the pulsed threshold observed in all previous OSL studies. Based on our analysis, we demonstrate a lasing duration of up to 100 μs by introducing a triplet manager into the OSL gain medium. The reduced triplet-induced loss of the triplet managed OSL decreases I_{CW} from 32 kW/cm² to a more practical value of 2.2 kW/cm² observed here.

### Measurements

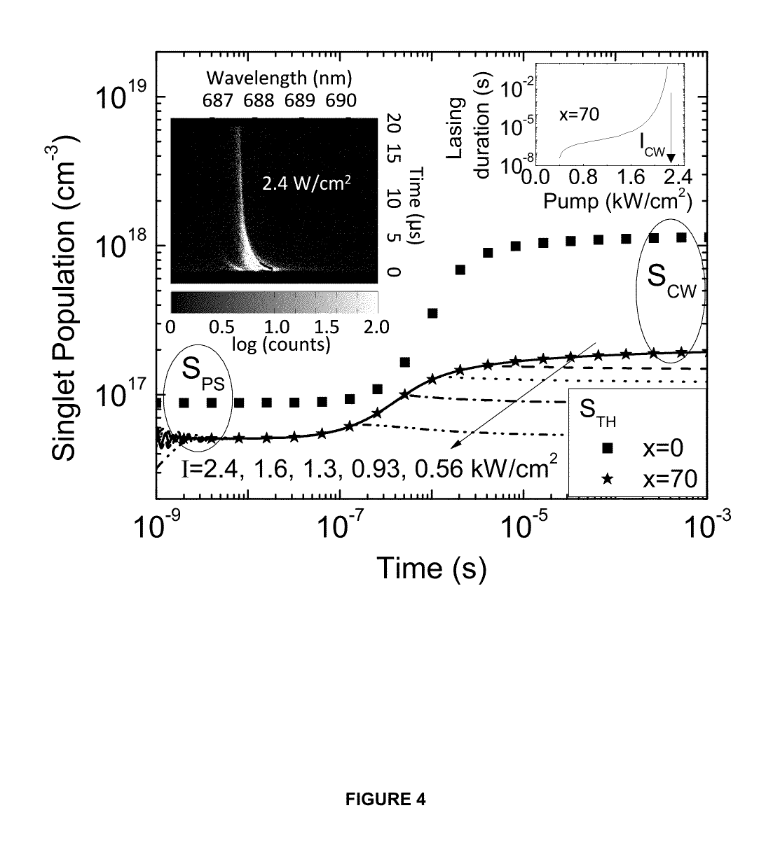

The singlet energy is derived from the peak of PL spectrum in FIG. 4 for ADN (S=2.83 eV), Alq3 (S=2.38 eV), and DCM2 (S=2.03 eV). The spectral overlap of the ADN and Alq₃ PL and DCM2 absorption, together with DCM2 emission in the lightly doped films, indicates efficient and complete Förster transfer of singlets generated in both host and manager to the guest. The 17 nm bathochromic shift in PL for the doped film is due to the solid-state solvation effect.

Triplet energies of the three fluorescence molecules are measured using the method of Tanaka et al., Phys. Rev. B 71 205207 (2005). Due to the negligible triplet emission of the fluorophores, the two phosphors: tris(2-phenylpyridine)Ir(III) (Ir(ppy)₃), T=2.4 eV) and bis(2-phenylquinoline) (acetylacetonate)Ir(III) (PQIr), T=2.1 eV) are co-doped with the material under study to enable efficient transfer of photogenerated triplets from the phosphor to the fluorophore, thereby overcoming its low intersystem crossing rate. The triplet energy of the phosphor is lower than the fluorophore singlet, but higher than its triplet for transfer to occur. Photoluminescence at 14K from the blends: Alq₃(25%)/Ir(ppy)₃(75%), DCM2(50%)/PQIr(50%), and ADN(50%)/Ir(ppy)₃(50%) using a N₂ pump laser (1 ns pulse) are measured using a streak camera (Hamamatsu C4334). The spectra at 0.4 ms to 9 ms after the pump pulses are shown in FIG. 4(b). Triplet energies of Alq₃ (T=1.99 eV), DCM2 (T=1.74 eV), and ADN (T=1.69 eV) are extracted from fits to Gaussians (solid lines). The Alq₃ triplet energy is consistent with that obtained by Tanaka, et al., Phys. Rev. B 71 205207 (2005).

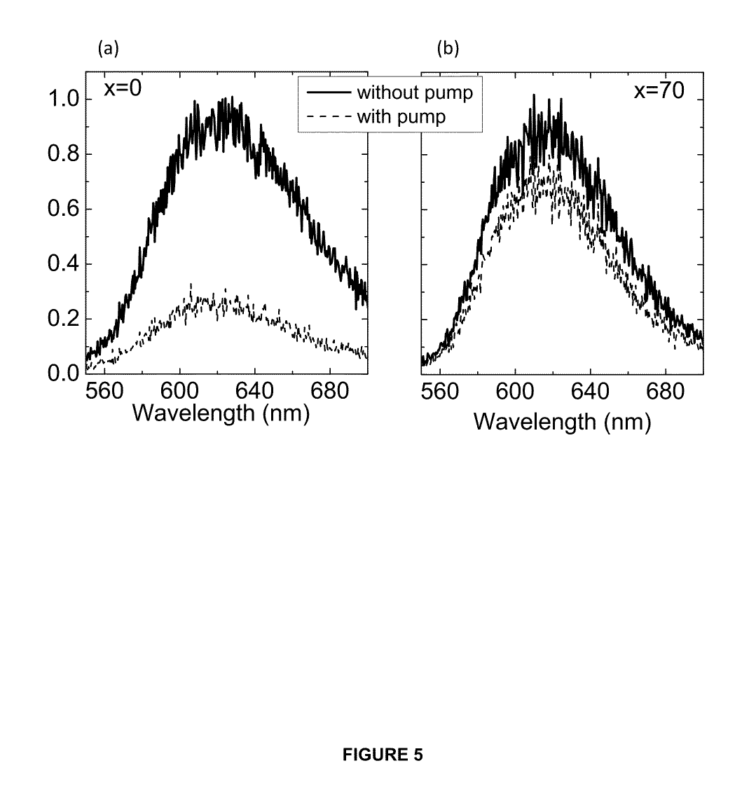

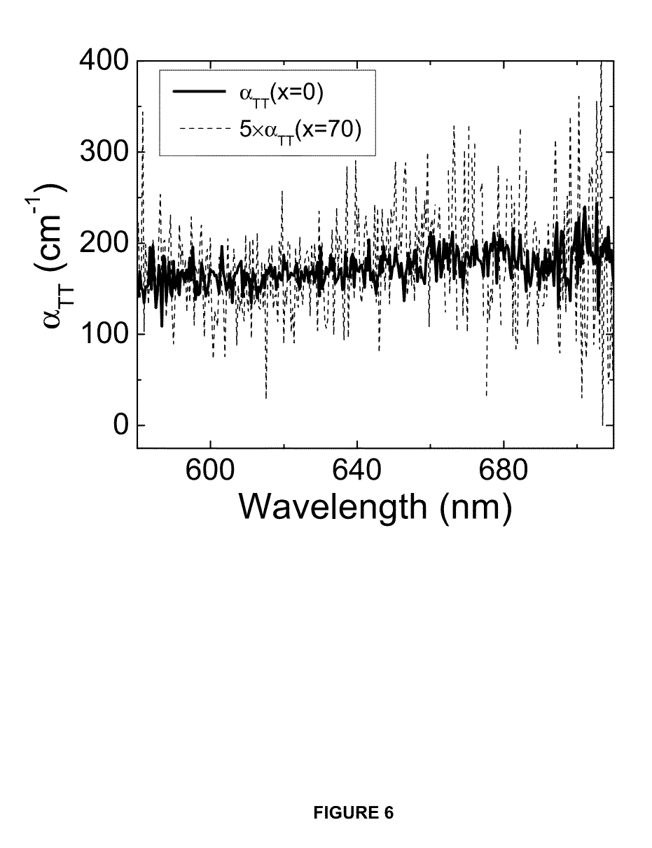

The triplet absorption is measured through spatially separated pump probe experiment proposed by Lehnhardt et al., Org. Electron. 12 486 (2011). The pump pulse from a λ=405 nm laser diode has 50 μs duration, saturating the guest triplet; the probe pulse from a N₂ (1.5 ns width) laser is applied 100 ns after the turn-off of the pump. The film PL is collected from the film edge by either a streak camera (Hamamatsu C4334) for absorption spectrum α_{TT}(λ) measurement, or through a λ=680±5 nm band-pass filter by an avalanche photodiode (C5658) for α_{TT} near the lasing wavelength with a smaller error. FIG. 5 shows the PL intensity from the probe with and without the pump pulse for x=0 and 70 films. We can see the triplet absorption is significantly reduced with introducing the triplet manager. From FIG. 5, two similar broad and featureless α_{TT}(λ) are obtained in FIG. 6, confirming that the absorptions are from the same excited state (guest triplet). As described above, the ˜5 times difference is from the different guest triplet saturation population, N₀.

A first device is provided. The device includes an organic semiconductor laser. The organic semiconductor laser further includes an optical cavity and an organic layer disposed within the optical cavity. The organic layer includes: an organic host compound; an organic emitting compound capable of fluorescent emission; and an organic dopant compound. The organic dopant compound may also be referred to herein as a “triplet manager.” The triplet energy of the organic dopant compound is lower than or equal to the triplet energy of the organic host compound. The triplet energy of the organic dopant compound is lower or equal to than the triplet energy of the organic emitting compound. The singlet energy of the organic emitting compound is lower than the singlet energy of the organic host compound.

The energy relationships described allows the organic dopant compound to drain triplets from the organic host compound and the organic emitting compound, and to avoid transfer of triplets from the organic dopant compound to the other compounds. The organic dopant compound also preferably has a triplet lifetime that is short relative to the organic host and organic emitting compounds, so that the organic dopant compound can drain many triplets over a period of time.

Triplet and singlet energies for a wide variety of compounds are readily available in the literature. Some of that literature is described herein. These energies may be measured, and they may also be calculated. There may be some differences in the values obtained from various measurement and calculation techniques. For purposes of comparing energies to see whether one is greater or less than another, it is preferred that the same or similar measurement or calculations be used to obtain the values to be compared. If a particular measurement or calculation tends to overestimate or underestimate energy values, using the same measurement or calculation to obtain all values being compared will minimize any such effect.

Preferably, the singlet energy of the organic emitting compound is lower than the singlet energy of the organic dopant compound.

This energy relationship minimizes transfer of singlets from the organic emitting compound to the organic dopant compound, so that the singlets on the organic emitting compound may desirably emit a photon.

Preferably, the organic dopant compound does not strongly absorb the fluorescent emission of the organic emitting compound.

By stating that the dopant compound “does not strongly absorb” the fluorescent emission of the emitting compound, it is meant that the ground, singlet excited and triplet-triplet excited states all have low absorption of the spectrum emitted by the fluorescent emitting compound. One of skill in the art can ascertain whether there is low absorption by observing plots of the emission and absorption spectra on the same graph, and checking whether there is significant overlap—some small overlap in the tail regions is permissible.

In one embodiment, the first device further includes an optical pump optically coupled to the organic layer.

In one embodiment, the organic semiconductor laser further includes an anode and a cathode. The organic layer is disposed between the anode and the cathode. A hole transport layer is disposed between the organic layer and the anode. An electron transport layer is disposed between the organic layer and the cathode. The organic dopant compound is present only in the emissive layer.

Preferably, the triplet decay time of the dopant compound is shorter than the triplet decay time of the emitting compound.

Preferably, the concentration of the dopant compound is 10 wt %-90 wt %, and the concentration of the emitting compound is 0.5 wt %-5 wt %.

In one embodiment, the host may be completely absent from the organic layer, i.e., the organic layer includes only the emitting compound and the dopant compound. In this situation, the concentration of the emitting compound is preferably 0.5 wt %-5 wt %, with the remainder of the layer being the dopant compound. The preferred energy level relationships described herein for the dopant compound and the emitting compound still apply to this embodiment. The device may still include other organic layers, such as hole transport and electron transport layers—this embodiment relates to a two-component emitting layer having the dopant and the emitting compound, but the rest of the device may have any of the other components described herein.

Preferably, the organic emitting compound is capable of fluorescent emission at room temperature.

Preferably, the dopant compound is selected from the group consisting of: anthracene, tetracene, rubrene, and perylene and their derivatives. More preferably, the dopant compound is selected from anthracene and its derivatives are particularly preferred. More preferably, the dopant compound is ADN.

In some embodiments, the dopant compound is a phosphor. In some embodiments, the dopant compound is a fluorophore.

It is preferable to maximize the transfer of singlets from the host and dopant to the emitting compound. The co-system of host and dopant (without an emitting compound) may have different emission spectra for different dopant concentrations. For an optimized concentrations, the overlap between this emission spectra and the guest absorption spectrum is maximized. The result of such maximization is increased or possibly complete singlet transfer to the emitting compound. This is a more detailed condition than the condition that the singlet energy of the emitting compound is simply less than the singlet energy of the host and the singlet energy of the dopant.

It is preferable to maximize the transfer of triplets from the host and the emitting compound to the dopant. A higher dopant concentration will result in more efficient triplet transfer from the emitting compound and the host to the dopant. This is a more specific condition than the condition that the triplet energy of the dopant is less than or equal to the triplet energy of the host and the emitting compound. However, if the dopant concentration is too high, transfer of singlets to the emitting compound may be compromised. Also, too high a dopant concentration can result in faster device degradation.

For embodiments where the laser is pumped electrically, i.e., where the emissive layer is between an anode and a cathode, t is also preferable to select concentrations of the emitting compound, the host and the dopant that result in the highest emitting layer mobility.

In some embodiments, the triplet energy of the dopant compound is preferably greater than 1.3 eV, and more preferably greater than 1.6 eV. 130 kJ/mol is around 1.3 eV If the triplet energy of the host material is sufficiently high, the triplet sink dopant triplet energy may also be high. For example, anthracene (1.6 eV triplet exciton) as a triplet sink in Alq₃ is an example. The use of high energy materials as described herein enables hosts that are capable of supporting high energy fluorescent emitters, such as blue-emitting emitters. Because technology for organic emitting compounds is generally weaker for blue emitters, the use of high energy hosts and triplet sinks to improve the performance of blue-emitting fluorescent laser devices is a particularly desirable result. In a particularly preferred embodiment, the triplet energy of the dopant compound is at least 1.3 eV, preferably at least 1.6 eV, and not more than 1.7 eV for the reasons described herein.

The first device may be a consumer product. In the context of this application, such a consumer product include any product available for purchase that includes a laser. Examples include printers, communications equipment, CD/DVD devices, and many other well known products. One of skill in the art can readily substitute the lasers described herein for the conventional lasers already used in such consumer products.

A method is provided. An organic semiconductor laser is provided. The organic semiconductor laser further includes an optical cavity and an organic layer disposed within the optical cavity. The organic layer includes: an organic host compound; an organic emitting compound capable of fluorescent emission; and an organic dopant compound. The organic dopant compound may also be referred to herein as a “triplet manager.” The triplet energy of the organic dopant compound is lower than or equal to the triplet energy of the organic host compound. The triplet energy of the organic dopant compound is lower or equal to than the triplet energy of the organic emitting compound. The singlet energy of the organic emitting compound is lower than the singlet energy of the organic host compound. The organic semiconductor laser is pumped to achieve lasing.

In one embodiment, the pumping is optical pumping.

In one embodiment, the pumping is electrical pumping.

When the organic semiconductor laser is pumped, lasing is achieved for at least 1 microsecond.

In some embodiments, the organic semiconductor laser is pumped at a power that exceeds the pulse threshold.

In some embodiments, the organic semiconductor laser is pumped at a power that exceeds the continuous wave threshold.

In some embodiment, the organic semiconductor laser is pumped at a power that exceeds the continuous wave threshold for at least 1 microsecond, and more preferably for at least 100 microseconds.

It is understood that the various embodiments described herein are by way of example only, and are not intended to limit the scope of the invention. For example, many of the materials and structures described herein may be substituted with other materials and structures without deviating from the spirit of the invention. The present invention as claimed may therefore includes variations from the particular examples and preferred embodiments described herein, as will be apparent to one of skill in the art. It is understood that various theories as to why the invention works, and modeling of specific configurations, are not intended to be limiting.

1. A first device, further comprising:
an organic semiconductor laser, further comprising:
an optical cavity;
an organic layer disposed within the optical cavity, the organic layer comprising:
an organic host compound;
an organic emitting compound capable of fluorescent emission; and
an organic dopant compound;
wherein:
the triplet energy of the organic dopant compound is lower than or equal to the triplet energy of the organic host compound;
the triplet energy of the organic dopant compound is lower or equal to than the triplet energy of the organic emitting compound;
the singlet energy of the organic emitting compound is lower than the singlet energy of the organic host compound.

2. The first device of claim 1, wherein the singlet energy of the organic emitting compound is lower than the singlet energy of the organic dopant compound.

3. The first device of claim 1, wherein the organic dopant compound does not strongly absorb the fluorescent emission of the organic emitting compound.

4. The first device of claim 1, further comprising an optical pump optically coupled to the organic layer.

5. The first device of claim 1, wherein the organic semiconductor laser further comprises:
an anode;
a cathode;
wherein the organic layer is disposed between the anode and the cathode;
a hole transport layer disposed between the organic layer and the anode; and
an electron transport layer disposed between the organic layer and the cathode;
wherein the organic dopant compound is present only in the emissive layer.

6. The first device of claim 1, wherein the triplet decay time of the dopant compound is shorter than the triplet decay time of the emitting compound

7. The first device of claim 1, wherein:
the concentration of the dopant compound is 10 wt %-90 wt %;
the concentration of the emitting compound is 0.5 wt %-5 wt %.

8. The first device of claim 1, wherein the organic emitting compound is capable of fluorescent emission at room temperature.

9. The first device of claim 1, wherein the dopant compound is selected from the group consisting of: anthracene, tetracene, rubrene, and perylene and their derivatives.

10. The first device of claim 1, wherein the dopant compound is selected from anthracene and its derivatives.

11. The first device of claim 10, wherein the dopant compound is ADN.

12. The first device of claim 1, wherein the dopant compound is a phosphor.

13. The first device of claim 1, wherein the dopant compound is a fluorophore.

14. The first device of claim 1, wherein the first device is a consumer product.

15. A method, comprising:
providing an organic semiconductor laser, further comprising:
an optical cavity;
an organic layer disposed within the optical cavity, the organic layer comprising:
an organic host compound;
an organic emitting compound capable of fluorescent emission; and
an organic dopant compound;
wherein:
the triplet energy of the organic dopant compound is lower than or equal to the triplet energy of the organic host compound;
the triplet energy of the organic dopant compound is lower or equal to than the triplet energy of the organic emitting compound;
the singlet energy of the organic emitting compound is lower than the singlet energy of the organic host compound;
pumping the organic semiconductor laser to achieve lasing.

16. The method of claim 15, wherein the pumping is optical pumping.

17. The method of claim 15, wherein the pumping is electrical pumping.

18. The method of claim 15, wherein lasing is achieved for at least 1 microsecond.

19. The method of claim 15, wherein the organic semiconductor laser is pumped at a power that exceeds the pulse threshold.

20. The method of claim 15, wherein the organic semiconductor laser is pumped at a power that exceeds the continuous wave threshold.

21. The method of claim 15, wherein the organic semiconductor laser is pumped at a power that exceeds the continuous wave threshold for at least 1 microsecond.

22. The method of claim 15, wherein the organic semiconductor laser is pumped at a power that exceeds the continuous wave threshold for at least 100 microseconds.
